(19) United States
(12) Patent Application Publication
(10) Pub. No.: US 2017/0110194 A1
(43) Pub. Date: Apr. 20, 2017

(54) Power Driven Optimization For Flash Memory

(71) Applicant: Silicon Storage Technology, Inc., San Jose, CA (US)

(72) Inventors: Vipin Tiwari, Dublin, CA (US); Nhan Do, Saratoga, CA (US)

(21) Appl. No.: 15/244,947

(22) Filed: Aug. 23, 2016

Related U.S. Application Data
(60) Provisional application No. 62/243,581, filed on Oct. 19, 2015.

(51) Int. Cl. G11C 16/12; G11C 16/26; G11C 16/30; G11C 16/14

(52) U.S. Cl. CPC G11C 16/12; G11C 16/14; G11C 16/26; G11C 16/30

(57) ABSTRACT

A memory device, and method of operation, includes an array of non-volatile memory cells and a controller. The controller is configured to perform an operation (e.g. erase, program, etc.) on a first plurality of the non-volatile memory cells using operational voltages with a first energy margin, and perform the same operation on a second plurality of the non-volatile memory cells using operational voltages with a second energy margin that is greater than the first energy margin. The operations of varying energy margins are based on the required storage longevity of the data being stored (lower energy margins for data being stored for shorter periods of time) to save energy and wear.

### RELATED APPLICATIONS

This application claims the benefit of U.S. Provisional Application No. 62/243,581, filed Oct. 19, 2015, and which is incorporated herein by reference.

### FIELD OF THE INVENTION

The present invention relates to non-volatile memory devices, and more particularly to optimization of operational voltages.

### BACKGROUND OF THE INVENTION

Non-volatile memory devices are well known in the art. For example, a split-gate memory cell is disclosed in U.S. Pat. No. 5,029,130 (which is incorporated herein by reference for all purposes). This memory cell has a floating gate and a control gate disposed over and controlling the conductivity of a channel region of the substrate extending between source and drain regions. Various combinations of voltages are applied to the control gate, source and drain to program the memory cell (by injecting electrons onto the floating gate), to erase the memory cell (by removing electrons from the floating gate), and to read the memory cell (by measuring or detecting the conductivity of the channel region to determine the programming state of the floating gate).

The configuration and number of gates in non-volatile memory cells can vary. For example, U.S. Pat. No. 7,315,056 (which is incorporated herein by reference for all purposes) discloses a memory cell that additionally includes a program/erase gate over the source region. U.S. Pat. No. 7,868,375 (which is incorporated herein by reference for all purposes) discloses a memory cell that additionally includes an erase gate over the source region and a coupling gate over the floating gate.

For all the above referenced memory cells, voltages are applied in each of the program, erase and read operations to ensure the proper operation of the memory cell array. Typically such devices are always configured for data retention of a uniform time period, and preferably any given memory cell in the array will maintain its programmed state over long periods of time (i.e. years), and maintain its ability to reliably determine (read) that programmed state. This is especially so where the memory array is embedded with logic devices that rely on the memory to store data over long periods of time (e.g., storing operating system software and updates).

However, over long periods of time, the electrical performance or state of the memory cells can drift or vary. Therefore, to ensure reliable performance over time, memory devices are typically designed to operate with a predetermined energy margin for each operation (i.e. increased operational voltage(s) or power(s) over what is minimally required to operate) to ensure proper operation. For example, the amplitude and/or duration of the program voltages are increased by a certain energy margin to over-program the memory cell (i.e. place an extra number of electrons on the floating gate) and to over-erase the memory cell (i.e. excessive depletion of electrons from the floating gate) to ensure that any change in the memory cell's condition over time will not affect its determined state anytime that state is read by the device.

While operating the memory device using energy margins for each operation ensures long term performance of the memory device, it does have several drawbacks. First, the additional energy margins require more power, which is problematic for battery operated devices and applications. Second, over-programming and over-erasing memory cells causes excessive wear on those cells (i.e. non-volatile memory can slightly degrade with each program/erase cycle), which can unduly shorten the lifespan of the memory array. There is a need for a non-volatile memory array operational technique that reduces the energy margins needed for the various operations, avoids excessive wear, yet still meets the storage longevity required for the particular data being stored.

### BRIEF SUMMARY OF THE INVENTION

The aforementioned problems and needs are addressed by a memory device that includes an array of non-volatile memory cells and a controller. The controller is configured to perform an operation on a first plurality of the non-volatile memory cells using operational voltages with a first energy margin, and perform the operation on a second plurality of the non-volatile memory cells using operational voltages with a second energy margin that is greater than the first energy margin.

A method of operating a memory device having an array of non-volatile memory cells includes performing an operation on a first plurality of the non-volatile memory cells using operational voltages with a first energy margin, and performing the operation on a second plurality of the non-volatile memory cells using operational voltages with a second energy margin that is greater than the first energy margin.

Other objects and features of the present invention will become apparent by a review of the specification, claims and appended figures.

### BRIEF DESCRIPTION OF THE DRAWINGS

FIG. 1 is a side cross sectional view of a first split gate non-volatile memory cell.

FIG. 2 is a side cross sectional view of a second split gate non-volatile memory cell.

FIG. 3 is a side cross sectional view of a third split gate non-volatile memory cell.

FIG. 4 is a plan view of the memory device architecture of the present invention.

### DETAILED DESCRIPTION OF THE INVENTION

The present invention is directed to non-volatile memory devices used for applications where different types of data are stored for different lengths of time. For example, an application may call for certain data to be stored for only a single day, while other data is stored for only a week, while still other data is stored for only a month, and still other data is stored for years. One such example could be a thermostat, that records temperature information to be stored on a daily basis only, a weekly basis only, a monthly basis only, and over many years.

The present invention is a system, method and technique of varying the program and erase energy margins depending on the required storage longevity of the data being stored. Therefore, in the example given, memory cells storing data for only one day would be programmed and erased utilizing very low energy margins (energy margins sufficient to ensure reliable data retention longevity of at least just one day). Memory cells storing data for one week would be programmed and erased utilizing marginally higher energy margins (energy margins sufficient to ensure reliable data retention longevity of at least just one week). Memory cells storing data for one month would be programmed and erased utilizing still higher energy margins (energy margins sufficient to ensure reliable data retention longevity of at least just one month). Memory cells storing data for very long periods of time (i.e. years) would be programmed and erased utilizing maximum energy margins (energy margins sufficient to ensure reliable data retention longevity of at least many years).

Varying the energy margins used to program and erase memory cells based on the storage longevity needs of the data being stored in those memory cells will reduce the overall power consumption of the device (i.e. for those memory cells being programmed with lower energy margins), as less energy is consumed for generating lower operational voltages and/or currents. Memory cell wear would also be reduced for those memory cells being programmed with lower energy margins. This program/erase technique can be applied each time a memory cell is programmed and/or erased (i.e. memory cells need not be preselected for any given data longevity range). Therefore, different memory cells adjacent to each other in the same memory array block can be programmed/erased using different energy margins. Additionally, any given memory cell can be programmed/erased once using one energy margin for one data of desired storage longevity, and again later using a different energy margin for another data of different desired storage longevity. As part of active wear leveling, the memory device can track how many times any given memory cell has been programmed/erased using the various energy margins, and rotate the assignments accordingly (i.e. a memory cell with many low margin programs/erases would be selected for a high energy margin, longer longevity data program/erase, and vice versa). Therefore, there is no need to pre-designate which memory cells would be used for which category of storage longevity, as this could change dynamically over time.

There are many advantages to the above described memory program/erase technique and device. Data for multiple, different applications, with different data longevity needs, can be stored in the same memory array. Data for each application could have its own storage shelf life depending on the type and needs of the application. Data for applications with a shorter storage shelf life can be written with lower energy (i.e. lower voltages and currents). The same application space could be replaced by another application which requires a different storage shelf life, so each memory cell space is capable different storage shelf lives. The storage shelf-life decision can be made by a decision-engine based on the application for which the data is used, based on the data itself, and/or on externally provided information/signal/flag.

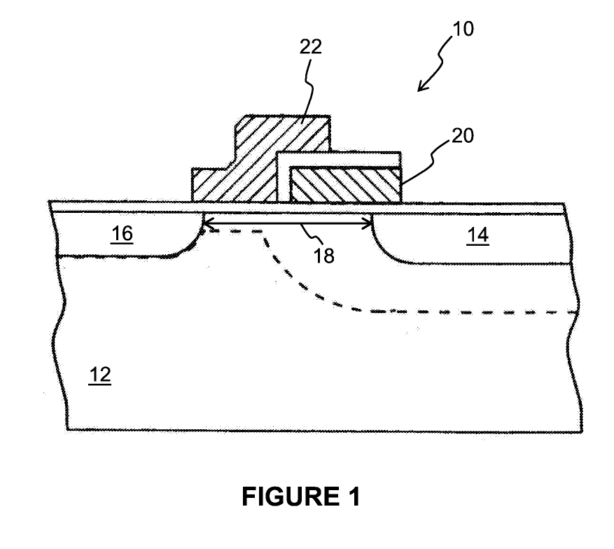

The technique of varying energy margins can be implemented in any non-volatile memory cell design. For example, FIG. 1 illustrates a split gate memory cell 10 with spaced apart source and drain regions 14/16 formed in a silicon semiconductor substrate 12. A channel region 18 of the substrate is defined between the source/drain regions 14/16. A floating gate 20 is disposed over and insulated from a first portion of the channel region 18 (and partially over and insulated from the source region 14). A control gate (also referred to as a word line gate or select gate) 22 has a lower portion disposed over and insulated from a second portion of the channel region 18, and an upper portion that extends up and over the floating gate 20 (i.e., the control gate 22 wraps around an upper edge of the floating gate 20).

Memory cell 10 can be erased by placing a high positive voltage on the control gate 22, and a reference potential on the source and drain regions 14/16. The high voltage drop between the floating gate 20 and control gate 22 will cause electrons on the floating gate 20 to tunnel from the floating gate 20, through the intervening insulation, to the control gate 22 by the well-known Fowler-Nordheim tunneling mechanism (leaving the floating gate 20 positively charged—the erased state). Memory cell 10 can be programmed by applying a ground potential to drain region 16, a positive voltage on source region 14, and a positive voltage on the control gate 22. Electrons will then flow from the drain region 16 toward the source region 14, with some electrons becoming accelerated and heated whereby they are injected onto the floating gate 20 (leaving the floating gate negatively charged—the programmed state). Memory cell 10 can be read by placing ground potential on the drain region 16, a positive voltage on the source region 14 and a positive voltage on the control gate 22 (turning on the channel region portion under the control gate 22). If the floating gate is positively charged (erased), electrical current will flow from source region 14 to drain region 16 (i.e. the memory cell 10 is sensed to be in its erased “1” state based on sensed current flow). If the floating gate 20 is negatively charged (programmed), the channel region under the floating gate is weakly turned on or turned off, thereby reducing or preventing any current flow (i.e., the memory cell 10 is sensed to be in its programmed “0” state based on sensed low or no current flow).

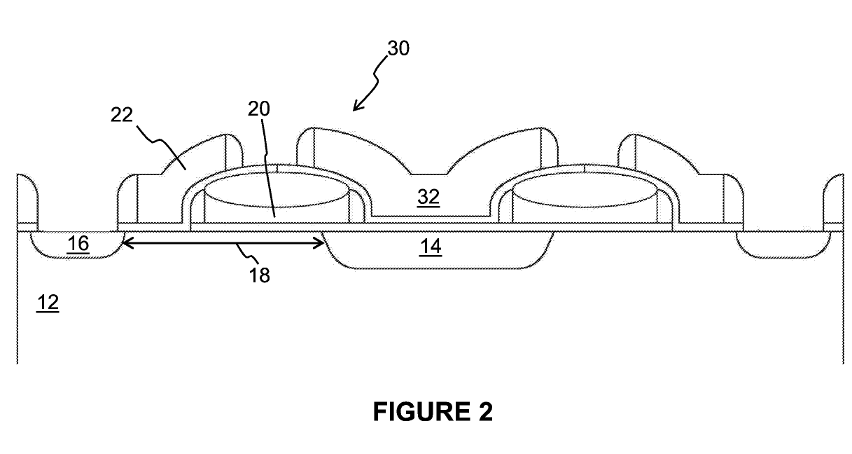

FIG. 2 illustrates an alternate split gate memory cell 30 with same elements as memory cell 10, but additionally with a program/erase (PE) gate 32 disposed over and insulated from the source region 14 (i.e. this is a three gate design). Memory cell 30 can be erased by placing a high voltage on the PE gate 32 to induce tunneling of electrons from the floating gate 20 to the PE gate 32. Memory cell 30 can be programmed by placing positive voltages on the control gate 22, PE gate 32 and source region 14, and a current on drain region 16, to inject electrons from the current flowing through the channel region 18 onto floating gate 20. Memory cell 30 can be read by placing positive voltages on the control gate 22 and drain region 16, and sensing current flow.

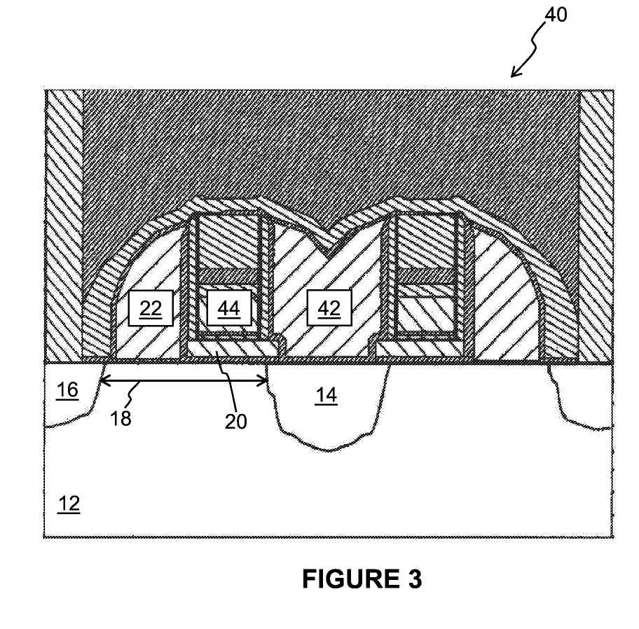

FIG. 3 illustrates an alternate split gate memory cell 40 with same elements as memory cell 10, but additionally with an erase gate 42 disposed over and insulated from the source region 14, and a coupling gate 44 over and insulated from the floating gate 20. Memory cell 40 can be erased by placing a high voltage on the erase gate 42 and optionally a negative voltage on the coupling gate 44 to induce tunneling of electrons from the floating gate 20 to the erase gate 42. Memory cell 40 can be programmed by placing positive voltages on the control gate 22, erase gate 42, coupling gate 44 and source region 14, and a current on drain region 16, to inject electrons from the current flowing through the channel region 18 onto floating gate 20. Memory cell 30 can be read by placing positive voltages on the control gate 22 and drain region 16 (and optionally on the erase gate 42 and/or the coupling gate 44), and sensing current flow.

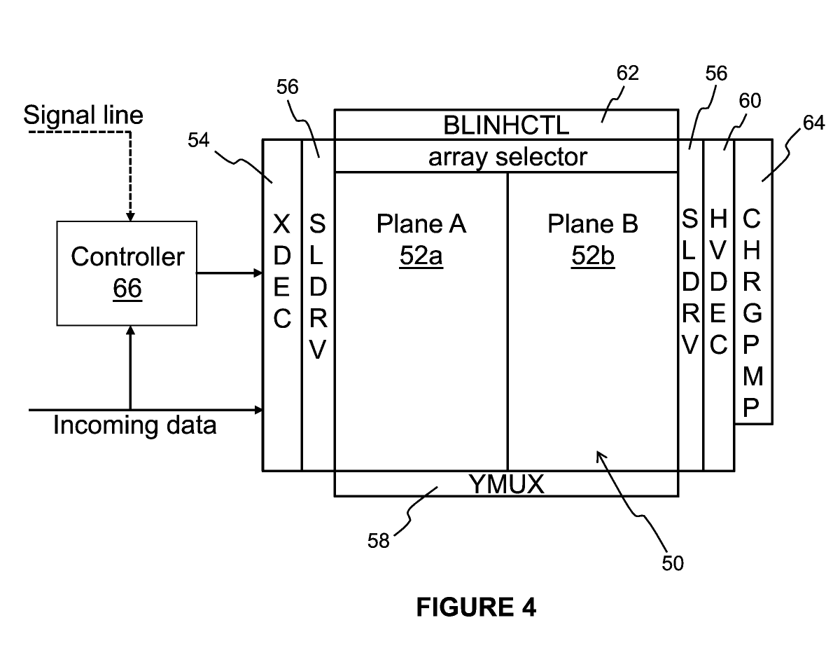

The architecture of the memory device of the present invention is illustrated in FIG. 4. The memory device includes an array 50 of non-volatile memory cells, which can be segregated into two separate planes (Plane A 52a and Plane B 52b). The memory cells can be of the type shown in FIGS. 1-3, formed on a single chip, arranged in a plurality of rows and columns in the semiconductor substrate 12. Adjacent to the array of non-volatile memory cells are address decoders (e.g. XDEC 54 (row decoder), SLDRV 56, YMUX 58 (column decoder), HVDEC 60) and a bit line controller (BLINHCTL 62), which are used to decode addresses and supply the various voltages to the various memory cell gates and regions during read, program, and erase operations for selected memory cells. Controller 66 (containing control circuitry) controls the various device elements to implement each operation (program, erase, read) on target memory cells. Charge pump CHRGPMP 64 provides the various voltages used to read, program and erase the memory cells under the control of the controller 66.

The controller 66 determines or is provided with the desired or indicated storage longevity level of incoming data, and then controls the program/erase operations accordingly. Based on the determined storage longevity level of the data, the charge pump 64 generating the various program/erase voltages is commanded to generate voltages having the desired energy margin based on the storage longevity for that data, and then the program/erase operations for that data are performed with the appropriate voltages/energies. Higher energy margins are used for applications having data with higher storage longevity needs, and lower energy margins are used for applications having data with lower storage longevity needs. While the read operation will typically use the same energy margin for all the data of any storage longevity, if the memory device employs a program verify operation to verify the program was performed correctly, the read verify operation can employ a lower energy margin for data having lower storage longevity, and vice versa.

The controller 66 can determine the appropriate energy margin for any given data in several different ways. Specifically, the desired storage longevity level of the data (and thus the desired energy margins) can be determined by the controller itself from the data itself (e.g. data type, embedded flag, detected internal code or code type, etc., indicating the the storage longevity level, etc.), by the application from which the data originates (e.g. application type), or from signals or flags provided by the application or other source to the controller over an optional signal line.

The energy used to program or erase data is a function of voltage(s) multiplied by the current(s) multiplied by the time duration(s) multiplied by number(s) of pulses if greater than one. Any of these four values individually or collectively (voltage, current, time and/or number of pulses) can be varied to affect the overall energy margin of any given program or erase operation. The following are four non-limiting examples of how the energy margin can be varied based upon the data's storage longevity:

### EXAMPLE 1

Standard Erase Operation=one 11 volt pulse of 10 ms in duration.

Lower Energy Margin Erase Operation:
(a) shorter duration: one 11 volt pulse of 5 ms in duration, or
(b) lower voltage pulse: one 10 volt pulse of 10 ms in duration, or
(c) a combination of both (a) and (b) above.

### EXAMPLE 2

Standard Erase Operation=4 pulses each of 1 ms, 11 volts

Lower Energy Margin Erase Operation
(a) fewer pulses: 2 pulses each of 1 ms, 11 volts, or
(b) lower voltage pulses: 4 pulses each of 1 ms, 10 volts, or
(c) shorter pulses: 4 pulses each of 0.5 ms, 11 volts, or
(d) any combination of (a)-(c) above.

### EXAMPLE 3

Standard Program Operation=one 8 volt pulse of 10 μs in duration

Lower Energy Margin Program Operation
(a) shorter duration=one 8 volt pulse of 5 μs in duration, or
(b) lower voltage pulse: one 6 volt pulse of 10 μs in duration, or
(c) a combination of both (a) and (b) above.

### EXAMPLE 4

Standard Program Operation: 4 pulses each of 2 μs, 8 volts.

Lower Energy Margin Program Operation
(a) fewer pulses: 2 pulses each of 2 μs, 8 volts, or
(b) lower voltage pulses: 4 pulses each of 2 μs, 6 volts, or
(c) shorter pulses: 4 pulses each of 1 μs, 8 volts, or
(d) any combination of (a)-(c) above.

As evident from the above examples, any given energy margin is defined by all of the parameters of all the voltages applied for the given operation (including zero/ground applied voltages). In each of the above examples or any other implementation, a lower energy margin can be achieved by lowering just one parameter of one operational voltage, multiple parameters of one operational voltage, one parameter of multiple operational voltages, multiple parameters of multiple operational voltages, or any combination of the above, that are applied to implement the program, erase and/or read operation. In fact, the number of affected voltages in any given operation could be a factor in affecting the overall energy margin of the operation. For example, a first lower energy margin could be the reduction of one of the program voltages, and a second lower energy margin could be the reduction of two of the program voltages, and so on. The number of affected voltages could be used in any combination with variations in voltage, current, time and/or number of pulses) to implement different energy margins in programming and/or erasing. The above described lower energy margin operation is particularly applicable to the memory cell designs of FIGS. 1-3, but could be applied to any non-volatile memory array of any design.

It is to be understood that the present invention is not limited to the embodiment(s) described above and illustrated herein. For example, references to the present invention herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method steps need be performed in the exact order illustrated. The incoming data could pass through the controller 66 instead of merely being supplied to the controller as shown in FIG. 4. Lastly, single layers of material could be formed as multiple layers of such or similar materials, and vice versa.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A memory device, comprising:
an array of non-volatile memory cells; and
a controller configured to:
perform an operation on a first plurality of the non-volatile memory cells using operational voltages with a first energy margin, and
perform the operation on a second plurality of the non-volatile memory cells using operational voltages with a second energy margin that is greater than the first energy margin.

2. The device of claim 1, wherein the operation is programming.

3. The device of claim 1, wherein the operation is erasing.

4. The device of claim 1, wherein the operation is reading.

5. The device of claim 1, further comprising:
a charge pump for generating the operational voltages for performing the operation on the first plurality of the non-volatile memory cells, and for generating the operational voltages for performing the operation on the second plurality of the non-volatile memory cells.

6. The device of claim 2, the controller is further configured to:
determine a first data to be programmed to the first plurality of non-volatile memory cells is associated with a storage longevity that is less than a storage longevity associated with a second data to be programmed to the second plurality of non-volatile memory cells; and
utilize the first energy margin for performing the operation on the first plurality of non-volatile memory cells and utilize the second energy margin for performing the operation on the second plurality of non-volatile memory cells based upon the determination.

7. The device of claim 1, wherein the controller is further configured to:
utilize the first energy margin for performing the operation on the first plurality of non-volatile memory cells and utilize the second energy margin for performing the operation on the second plurality of non-volatile memory cells in response to a received signal.

8. The device of claim 1, wherein at least one of a voltage, a current, a time duration, and a number of pulses of the operational voltages for performing the operation on the second plurality of non-volatile memory cells is greater than that of the operational voltages for performing the operation on the first plurality of non-volatile memory cells.

9. The device of claim 1, wherein at least one voltage of the operational voltages for performing the operation on the second plurality of non-volatile memory cells is greater than that of the operational voltages for performing the operation on the first plurality of non-volatile memory cells.

10. The device of claim 1, wherein at least one current of the operational voltages for performing the operation on the second plurality of non-volatile memory cells is greater than that of the operational voltages for performing the operation on the first plurality of non-volatile memory cells.

11. The device of claim 1, wherein at least one time duration of the operational voltages for performing the operation on the second plurality of non-volatile memory cells is greater than that of the operational voltages for performing the operation on the first plurality of non-volatile memory cells.

12. The device of claim 1, wherein a number of pulses of the operational voltages for performing the operation on the second plurality of non-volatile memory cells is greater than that of the operational voltages for performing the operation on the first plurality of non-volatile memory cells.

13. A method of operating a memory device having an array of non-volatile memory cells, comprising:
performing an operation on a first plurality of the non-volatile memory cells using operational voltages with a first energy margin, and
performing the operation on a second plurality of the non-volatile memory cells using operational voltages with a second energy margin that is greater than the first energy margin.

14. The method of claim 13, wherein the operation is programming.

15. The method of claim 13, wherein the operation is erasing.

16. The method of claim 13, wherein the operation is reading.

17. The method of claim 14, further comprising:
determining a first data to be programmed to the first plurality of non-volatile memory cells is associated with a storage longevity that is less than a storage longevity associated with a second data to be programmed to the second plurality of non-volatile memory cells;
wherein the performing of the operation on the first plurality of non-volatile memory cells using the first energy margin and the performing of the operation on the second plurality of non-volatile memory cells using the second energy margin is based upon the determining.

18. The method of claim 13, wherein the performing of the operation on the first plurality of non-volatile memory cells using the first energy margin and the performing of the operation on the second plurality of non-volatile memory cells using the second energy margin is in response to a received signal.

19. The method of claim 13, wherein at least one of a voltage, a current, a time duration, and a number of pulses of the operational voltages in performing the operation on the second plurality of non-volatile memory cells is greater than that of the operational voltages in performing the operation on the first plurality of non-volatile memory cells.

20. The method of claim 13, wherein at least one voltage of the operational voltages in performing the operation on the second plurality of non-volatile memory cells is greater than that of the operational voltages in performing the operation on the first plurality of non-volatile memory cells.

21. The method of claim 13, wherein at least one current of the operational voltages in performing the operation on the second plurality of non-volatile memory cells is greater than that of the operational voltages in performing the operation on the first plurality of non-volatile memory cells.

22. The method of claim 13, wherein at least one time duration of the operational voltages in performing the operation on the second plurality of non-volatile memory cells is greater than that of the operational voltages in performing the operation on the first plurality of non-volatile memory cells.

23. The method of claim 13, wherein a number of pulses of the operational voltages in performing the operation on the second plurality of non-volatile memory cells is greater than that of the operational voltages in performing the operation on the first plurality of non-volatile memory cells.
